(19) United States
(12) Patent Application Publication
(10) Pub. No.: US 2011/0009090 A1
(43) Pub. Date: Jan. 13, 2011

(54) CELLULAR PHONE WITH BOUNDARY ALARM

(76) Inventor: Clifford Sparks, III, Miami Gardens, FL (US)

Correspondence Address: MUSKIN & CUSICK LLC, 100 West Main Street, SUITE 205, Lansdale, PA, 19446, US

(21) Appl. No.: 12/502,223

(22) Filed: Jul. 13, 2009

(51) Int. Cl. H04M 1/66; H04W 64/00; H03F 99/00

(52) U.S. Cl. 455/410; 455/456.1; 381/120

(57) ABSTRACT

A method and apparatus to provide an automatic alarm for a cell phone. A user of the cell phone can set a safe zone, which is a geographic area centered at a particular location with a circular boundary of a preset radius. If the cell phone is removed outside of this radius, the cell phone is presumably stolen, and thus an audible alarm on the cell phone can be triggered.

### BACKGROUND OF THE INVENTION

1. Field of the Invention

The present inventive concept relates to an alarm system for a cellular phone which can automatically detect removal from a particular geographic location.

2. Description of the Related Art

Cellular phones are currently easy to steal, especially considering their small size.

What is needed is a method in order to protect a cellular phone from being stolen.

### SUMMARY OF THE INVENTION

It is an aspect of the present general inventive concept to provide an alarm system which can assist in prevention of stolen cellular phones.

The above methods can be obtained by a method that includes (a) providing a cell phone; (b) executing a set of instructions embodied in software or hardware on the cell phone to perform the following operations: (c) identifying a current location of the cell phone; (d) determining if the current location falls outside of a safe zone, and if so, then triggering an alarm; and (e) repeating the identifying and the determining until the executing is terminated.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

Further features and advantages of the present invention, as well as the structure and operation of various embodiments of the present invention, will become apparent and more readily appreciated from the following description of the preferred embodiments, taken in conjunction with the accompanying drawings of which:

FIG. 1 is a flowchart illustrating a method used to implement an automated alert system, according to an embodiment;

FIG. 2 is a block diagram illustrating a cellular phone and a home location, according to an embodiment;

FIG. 3A is a flowchart illustrating an initialization process, according to an embodiment;

FIG. 3B is a drawing of a cell phone during the initialization of the alarm, according to an embodiment;

FIG. 4A is a flowchart illustrating a method used to turn off the alarm, according to an embodiment;

FIG. 4B is a drawing of a cell phone during the turning off of the alarm, according to an embodiment;

FIG. 5A is a drawing of an open amplifying bag or case, according to an embodiment;

FIG. 5B is a drawing of a closed amplifying bag or case, according to an embodiment; and

FIG. 6 is a block diagram of a sample hardware architecture for a cell phone (or other portable device), according to an embodiment.

### DESCRIPTION OF THE PREFERRED EMBODIMENTS

Reference will now be made in detail to the presently preferred embodiments of the invention, examples of which are illustrated in the accompanying drawings, wherein like reference numerals refer to like elements throughout.

Embodiments of the invention relate to a method, apparatus, and computer readable storage for preventing the theft of cellular phones. The method can operate as follows. A cellular phone can be calibrated with a particular geographical location and a radius from the location. The cellular phone can then continuously monitor its location and if the location falls outside the geographical radius, than an alert or an alarm can be triggered.

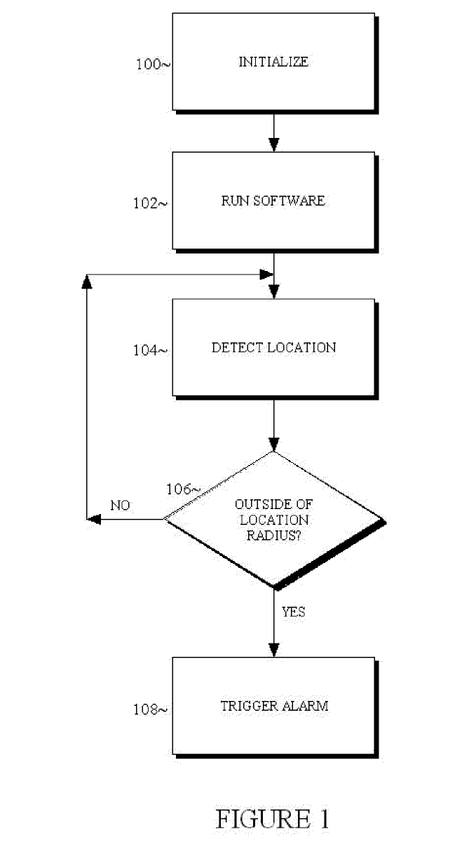

FIG. 1 is a flowchart illustrating a method used to implement an automated alert system, according to an embodiment.

The method can begin with operation 100, wherein a user initializes the alarm in the cell phone. The initialization procedure verifies the user and ascertains the home location of the cell. The home location is to be the location where the cell phone can rightfully stay without triggering an alarm. In addition to the location, the user can also enter a radius (e.g., 1 mile, 1000 feet, 10 miles) from the home location that the cellular phone can be located without triggering the alarm. Being inside this radius (the “safe zone”) will not trigger the alarm. The home location can be set, for example, by pressing a button on the cell phone which determines the cell phone's location. This can be determined by a Global Positioning System (GPS) system on the phone itself, or other mechanisms, such as using cellular stations to read the location of the cellular phone.

From operation 100, the method proceeds to operation 102, wherein the user instructs the cellular phone to run the software that will begin monitoring the cell phone's location.

From operation 102, the method proceeds to operation 104, which detects the current location of the cellular phone. This can be done using any method known in the art, such as GPS, triangulation, etc.

From operation 104, the method proceeds to operation 106, which determines whether the current location of the cellular phone (determined in operation 104) is outside of the radius from the home location (set in operation 100). If not, then the method returns to operation 104, which continues to detect the cellular phone's current location.

If the determination in operation 106 determines that the current location is outside the location radius, then the method proceeds to operation 108, which triggers an alarm. The alarm can come in numerous forms. For example, an audible alarm can sound which would hopefully alert people in close proximity to the alleged thief of the cellular phone, causing the thief to leave the cellular phone behind. The alarm can also silently call the police (using the cellular phone) and alert the police that there is a theft in progress and even transmit the cellular phone's current location to the police.

The user (owner) of the cell phone may desire to turn off the alarm (for example, when the user wishes to return home). The user can do so by pressing an icon or button on the cell phone which would trigger a software (or hardware) module to input a secret code from the user. If the user inputs the secret code correctly, then operations 104-106 can be stopped so that the cell phone can be removed outside of the safe zone without triggering the alarm.

Typically, without using the secret code (e.g., PIN number), the alarm cannot be turned off. In this way, a thief of the cell phone would not be able to turn the alarm off and thus he may leave the cell phone behind and run away.

In a further embodiment, an accelerometer can be used in addition to (or in place of) a GPS device. The accelerometer can also detect motion and can be programmed to also trigger the alarm based on a variety of conditions. For example, if the accelerometer detects a movement of the cell phone with a force greater than a predetermined threshold, then the alarm can be triggered. Continuous smaller movements can also trigger the alarm, for example if someone is running (or walking), the phone can detect such continuous motions and trigger the alarm.

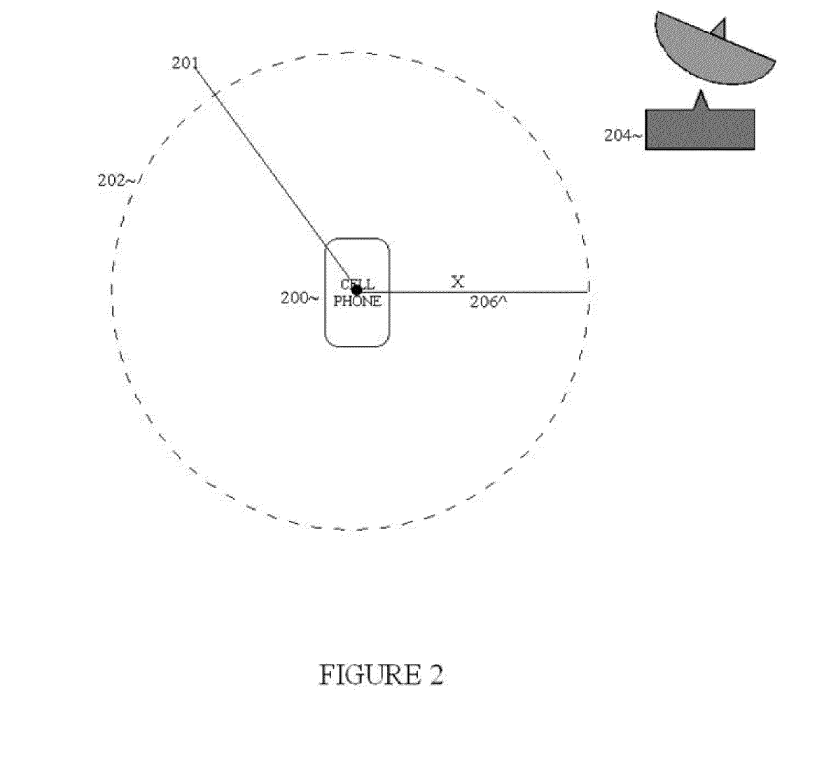

FIG. 2 is a block diagram illustrating a cellular phone and a home location, according to an embodiment. FIG. 2 can also be thought of as a “birds eye” view looking downward.

A cell phone 200 is initialized at a home point 201. The user can also indicate a radius 206 of length X as to which will be the safe zone 202. If the cell phone 200 is taken outside of the safe zone 202, then an alarm on the cell phone 200 will trigger.

Thus, for example, if X is 1,000 feet, then if the cell phone 200 is moved more than 1000 feet from the home point 201 then the alarm will trigger. Typically, the height of the cell phone does not matter and would not be considered as part of the distance, in other words the safe zone 202 can be thought of as a vertical cylinder with radius X. Thus, if X equals one mile, then traveling on the ground more than one mile in any direction from the home point 201 would trigger the alarm. In another embodiment, the safe zone 202 can be thought of as a three dimensional sphere with radius X, in other words, moving the cell phone 200 more than distance X in any 3 dimensional vector will trigger the alarm.

The location of the cell phone 200 can be determined in a number of ways (see operation 104). The cell phone 200 can determine its position locally, e.g., by having a built in Global Positioning System (GPS). Or the cell phone 200 can determine its location with the help of a cellular network and cellular towers 204, using current technologies such as GSM localization, triangulation, blue-tooth, hotspots, wifi detection, or any other known method. Once the network is able to determine the location of the cell phone 200, the location can then be transmitted using the cellular tower 204 (or a different one) to the cell phone 200.

Once the cell phone 200 knows its current location (which can be expressed in terms of coordinates), it can compute whether it falls inside the safe zone or not (operation 106).

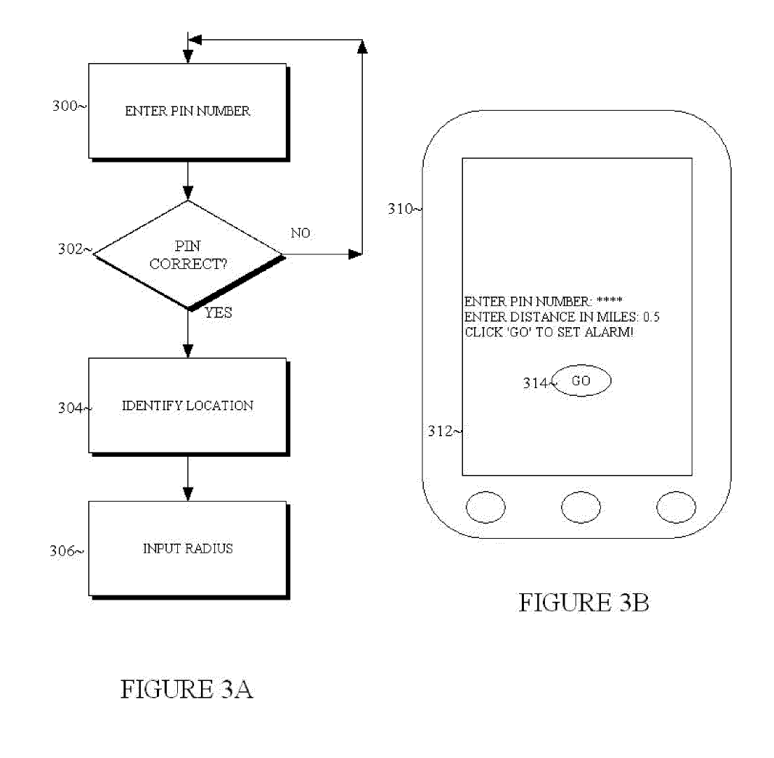

FIG. 3A is a flowchart illustrating an initialization process, according to an embodiment.

The initialization operation in operation 100 can be broken into sub-operations. A Personal Identification Number (PIN) can optionally be used to turn the alarm on, while the same PIN (or a different one) must be used to turn the alarm off (see operation 108). Alternatively to a PIN number, other mechanisms can be used to arm (turn the alarm on) and disarm (turn the alarm off). For example, voice recognition, fingerprint analysis, retinal scanning, or any other biometric system can be used. For such biometric systems to be used, the user must first teach the system the respective voice print, fingerprints, retina, etc., so the system will recognize the true owner.

After a user enters his or her pin number in operation 300, the method can proceed to operation 302, which determines whether the pin number is correct (e.g., matches a pre-stored PIN number stored on the cell phone). If the pin number entered in operation 300 is not correct, then the method can return to operation 300 wherein the user can try again to enter the PIN number.

If in operation 302, the PIN number entered in operation 300 is correct, then the method can proceed to operation 304 which identifies the cell phone's location. This can be done automatically using any of the methods described herein. The location is then stored locally on the cell phone, but the location can also be stored remotely on a server associated with the cell phone's carrier.

From operation 304, the method can proceed to operation 306, which inputs the radius from the user.

Thus, from operations 300 to 306, the cell phone has gathered all of the information it needs to initialize and thus set the alarm.

FIG. 3B is a drawing of a cell phone during the initialization of the alarm, according to an embodiment.

Data (such as the PIN number, radius, etc.) can be entered into the cell phone 310 using standard input/output techniques, such as using an output display 312 on the cell phone 310 and a keyboard (not pictured) or stylus, etc.

A button 314 can appear on output display 312 which can initiate the alarm, and allow the cell phone to proceed to operation 102 from FIG. 1.

When the alarm is activated (sounding a loud, highly audible, continuous alarm), there has to be a way for the owner of the cell phone to turn the alarm off, while preventing a thief from being able to turn the alarm off.

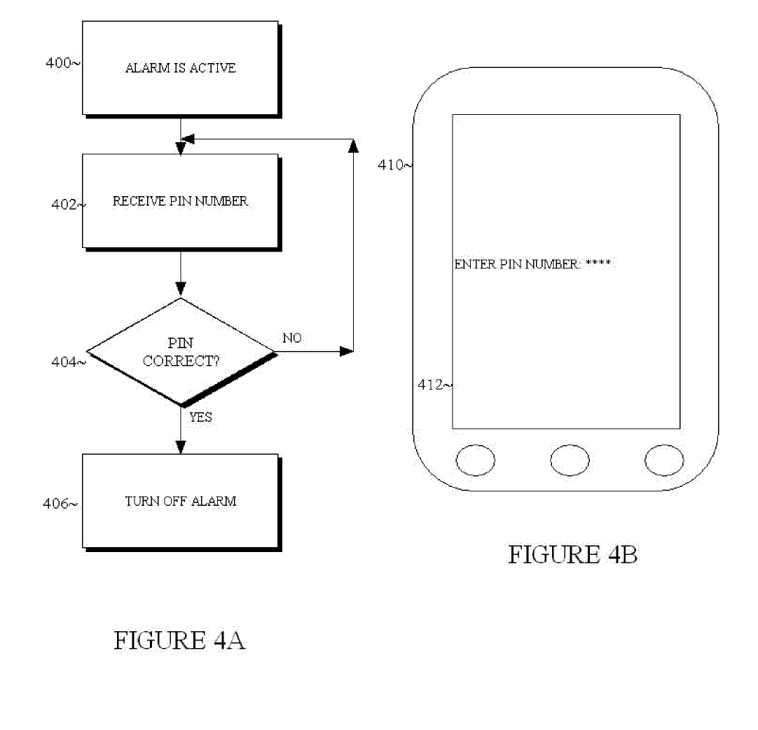

FIG. 4A is a flowchart illustrating a method used to turn off the alarm, according to an embodiment.

In operation 400, the alarm is active, presumably causing a commotion in the nearby area. An active alarm might also be calling the local police department with an electronic message indicating to them that this particular cell phone has been stolen and also including its location. While the alarm is active, the cell phone itself is typically unusable and cannot be used to place calls by someone holding the cell phone.

From operation 400, the method proceeds to operation 402, which receives a PIN number from the user of the cell phone. This can be done as described herein, such as using a keyboard, etc.

From operation 402, the method proceeds to operation 404, which determines if the PIN number entered in operation 402 is correct (e.g., matches a pre-stored PIN number). If not, then the method returns to operation 402, wherein the user can enter in another PIN number.

If operation 404 determines that the entered PIN number is correct, then the method proceeds to operation 406, which turns off the alarm, thus rendering the cell phone silent.

FIG. 4B is a drawing of a cell phone during the turning off of the alarm, according to an embodiment;

A cell phone 410 has an output display 412 which allows the user to type in a PIN number (during operation 402) in order to turn off the alarm.

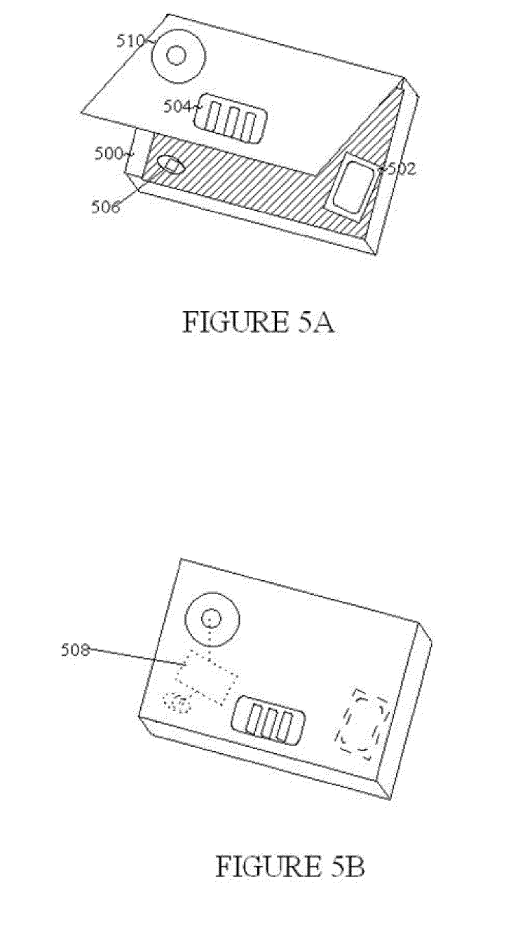

FIG. 5A is a drawing of an open amplifying bag or case, according to an embodiment. An amplifying carrying bag 500 (or case, briefcase, etc.) can be used in order to amplify the sound of the alarm.

A cell phone 502 is shown inserted into the bag 500. Once the cell phone 502 is inserted into the bag 500 completely, the bag 500 can be closed and a combination lock 504 (or other locking mechanism) can be used to lock the bag closed.

A microphone 506 is inside the bag, connected to a driving unit 508 (not pictured in FIG. 5A), which is connected to a speaker 510 which protrudes outside of the bag 500. The microphone 506 will pick up any sound generated inside the bag 500, and it will be amplified by the driving unit 508 and outputted to the speaker 510 which produces sound outside of the bag 506. The result is that any sound the cell phone makes (or anything else in the bag) will be greatly amplified. Thus, if the alarm on the cell phone 502 is triggered, the speaker 510 can generate an audible alarm louder than what the cell phone 502 could generate. The speaker 510 should typically be a loud speaker that can generate loud noises thereby drawing attention to the would-be thief when the alarm is triggered.

FIG. 5B is a drawing of a closed amplifying bag or case, according to an embodiment.

The driving unit 508 contains all of the necessary electronics, such as the power supply, wires, connections, amplifier, etc., in order to amplify the sounds picked up by the microphone 506 and broadcast them outside the bag 500 through the speaker 510.

The amplifying bag 500 can be useful for example on a beach. For example, an owner of a cell phone can set the radius to be 500 feet from where he or she has pitched their umbrella (the home location) on the beach. The owner's cell phone can be placed in the amplifying bag and closed using a locking mechanism (e.g., the combination lock 504) so that any would-be thief would not be able to remove the cell phone from the amplifying bag quickly. If a thief steals the bag and walks more than 500 feet away, the alarm on the cell phone will trigger, which will trigger a very loud alarm coming out of the speaker on the outside of the amplifying bag (thus heard loudly outside of the bag). This will serve multiple purposes: 1) the thief might be startled, and thus drop the bag and run away; or 2) the thief might realize what is going on but will not be able to quickly remove the cell phone from the bag, and thus drop the bag and run away.

The interior of the bag can also have a jack to plug in a portable music player, such as any type of MP3 player, which can play music from the MP3 player on the speaker thus broadcasting the music outside of the bag. A cellular phone (placed inside the bag) can also plug directly into a jack located on the inside of the back, wherein the cellular phone itself can generate the audio to be broadcasted on the speaker 510. In other words, when the alarm is triggered, the cell phone would generate an alarm which is then directly piped through such a jack to the speaker 510 which is then broadcasted outside of the bag. In this configuration, the microphone 506 is not necessary.

The interior of the bag can be made of a non-rust lightweight metal which can have various compartments, one of which can house a cell-phone. The exterior cover of the bag can be made of any material, such as a durable waterproof material that can be removed.

The interior of the bad can also (optionally) include (not pictured) an optical sensor which can detect light emanating from inside the bag (above a particular ambient level). This can be used to detect when the cell-phone inside the back has lit up (which would happen after the alarm has been triggered) which can then trigger an audio alarm which is broadcasted using the speaker 510.

The bag can also have a rope or handle (not pictured) that can be extended and tied to a fixed object (e.g., a tree), thereby securing the bag from theft.

The amplifying bag is not required in order to practice the location alarm on a cell phone as described herein, but is an optional addition. The bag may work best in locations where there are a lot of people and thus the thief would not have time to remove the cell phone from the bag.

If the bag (or safe) is made of all metal, there should typically be a portion to allow radio waves in and out. The phone compartment should be able to keep the phone safe if someone throws the bag/safe around. In addition to a microphone, the bag/safe can also have an optical sensor inside as well. The bag/safe can also contain a plug in jack that connects the cell phone to an antenna on an outside of the bag/safe to boost the radio signal to/from the cell phone.

All of the methods described herein can also be applied to other devices besides cellular phones, such as laptops, briefcases, and all other electronic devices.

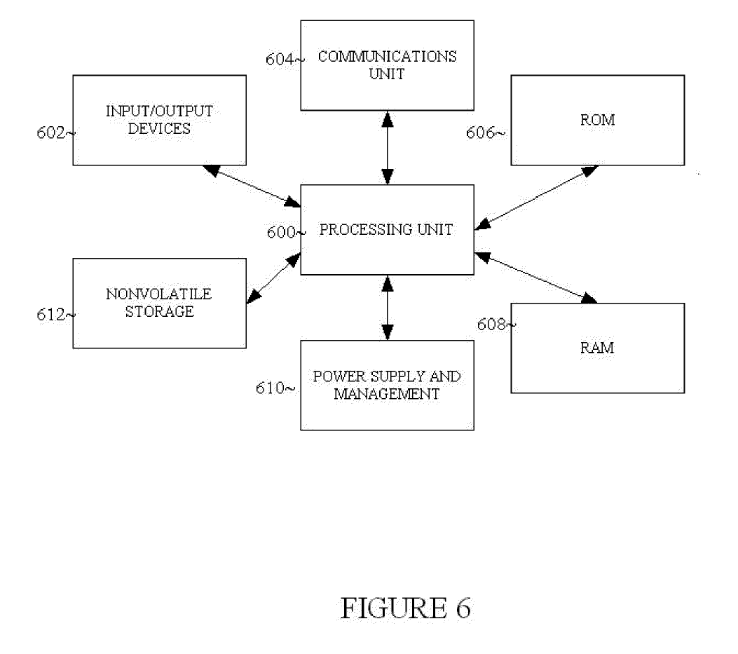

FIG. 6 is a block diagram of a sample hardware architecture for a cell phone (or other portable device), according to an embodiment.

A processing unit 600 can be any type of microprocessor including any associated devices, such as cache, bus, etc. Input/output devices 602 can be any mechanisms used for input and output, such as keys on a keyboard (input), an LCD screen (output), speakers (output), a touch sensitive screen (input and output), etc. A ROM 606 and RAM 608 can be used to implement the device as known in the art. Power supply and management 610 is used to provide power to all of the electronic devices. Nonvolatile storage 612 is used to store programs and data.

An application to perform all of the methods described herein (e.g., FIGS. 1, 3A and 3B, 4A and 4B) can be downloaded and installed on the nonvolatile storage 612 (or RAM 608) on a cellular phone. For example, an application can be installed on a cellular phone such as an I-PHONE and can be distributed using the I-PHONE'S “app store.” Of course the methods described herein can be implemented on any other platform as well.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A method to trigger an alarm on a cell phone, the method comprising:
providing a cell phone;
executing a set of instructions embodied in software or hardware on the cell phone to perform the following operations:
identifying a current location of the cell phone;
determining if the current location falls outside of a safe zone, and if so, then triggering an alarm; and
repeating the identifying and the determining until the executing is terminated.

2. The method as recited in claim 1, before the identifying, the set of instructions further performs:
receiving an indication from a user to set a home location;
inputting a radius from the user; and
identifying a current location of the cell phone,
wherein the safe zone is identified as a circular geographical location centered at the current location with the radius.

3. The method as recited in claim 1, wherein the triggering an alarm comprises initiating an audible alarm on the cell phone.

4. The method as recited in claim 1, wherein the triggering an alarm comprises automatically calling a security service.

5. The method as recited in claim 1, further comprising,
allowing a user of the cell phone to terminate the executing by entering a secret code into the cell phone.

6. The method as recited in claim 1, wherein the method is downloaded and installed as an application on the cellular phone.

7. An amplifying bag, comprising:
a bag;
a microphone located inside the bag;
a speaker which protrudes outside of the bag; and
a driving unit connected to the microphone and the speaker, wherein sounds inside the bag are picked up by the microphone, amplified, and outputted to the speaker, thus broadcasting the sounds outside of the bag.

8. The amplifying bag as recited in claim 7, wherein the amplifying bag further comprises:
a cell phone executing a set of instructions embodied in software or hardware on the cell phone to perform the following operations:
identifying a current location of the cell phone;
determining if the current location falls outside of a safe zone, and if so, then triggering an alarm; and
repeating the identifying and the determining until the executing is terminated.

9. The amplifying bag as recited in claim 7, further comprising a combination lock to lock the bag closed.

10. An amplifying bag, comprising:
a bag;
a speaker which protrudes outside of the bag;
a jack inside the bag, the jack connected to the speaker;
a cell phone, connected to the jack, executing a set of instructions embodied in software or hardware on the cell phone to perform the following operations:
identifying a current location of the cell phone;
determining if the current location falls outside of a safe zone, and if so, then triggering an alarm; and
repeating the identifying and the determining until the executing is terminated,
wherein when the triggering the alarm occurs, the cell phone generates sounds which are transmitted through the jack and played on the speaker which are heard outside the bag.

11. The amplifying bad as recited in claim 10, wherein before the identifying, the set of instructions further performs:
receiving an indication from a user to set a home location;
inputting a radius from the user; and
identifying a current location of the cell phone,
wherein the safe zone is identified as a circular geographical location centered at the current location with the radius.

12. The method as recited in claim 10, wherein the triggering an alarm comprises initiating an audible alarm on the cell phone.

13. The method as recited in claim 10, wherein the triggering an alarm comprises automatically calling a security service.

14. The method as recited in claim 10, further comprising,
allowing a user of the cell phone to terminate the executing by entering a secret code into the cell phone.

15. The method as recited in claim 10, wherein the method is downloaded and installed as an application on the cellular phone.
